(19) United States
(12) Patent Application Publication
(10) Pub. No.: US 2014/0183557 A1
(43) Pub. Date: Jul. 3, 2014

(54) SEMICONDUCTOR DEVICE STRUCTURE FOR OHMIC CONTACT AND METHOD FOR FABRICATING THE SAME

(71) Applicant: HYUNDAI MOTOR COMPANY, Seoul (KR)

(72) Inventors: Su Bin KANG, Busan (KR); Kyoung-Kook HONG, Gyeonggi-do (KR); Jong Seok LEE, Gyeonggi-do (KR); Youngkyun JUNG, Seoul (KR)

(73) Assignee: HYUNDAI MOTOR COMPANY, Seoul (KR)

(21) Appl. No.: 14/092,098

(22) Filed: Nov. 27, 2013

(30) Foreign Application Priority Data
Dec. 27, 2012 (KR) 10-2012-0155376

(51) Int. Cl. H01L 29/45; H01L 21/28; H01L 29/16

(52) U.S. Cl. CPC H01L 29/45; H01L 29/1608; H01L 21/28
USPC 257/77; 438/653

(57) ABSTRACT

A semiconductor device structure for an ohmic contact is provided, including a silicon carbide substrate and an ohmic contact layer disposed on the silicon carbide substrate. A carbon layer is disposed on the ohmic contact layer. An anti-diffusion layer is disposed on the carbon layer, and a pad layer is disposed on the anti-diffusion layer. The anti-diffusion layer is made of any one of tungsten (W), titanium (Ti), titanium nitride (TiN), tantalum (Ta), and tantalum nitride (TaN).

### CROSS-REFERENCE TO RELATED APPLICATION

This application claims priority to and the benefit of Korean Patent Application No. 1 0-201 2-01 55376 filed in the Korean Intellectual Property Office on Dec. 27, 2012, the entire contents of which are incorporated herein by reference.

### TECHNICAL FIELD

The present disclosure relates to a semiconductor device structure for an ohmic contact, and a method for fabricating the same.

### BACKGROUND

With the recent trend toward large-sized and large-capacity application apparatuses, a power semiconductor device having a high breakdown voltage, a high current capacity, and high-speed switching characteristics has become necessary. A silicon carbide (SiC) power element is spotlighted as a device capable of meeting the above-mentioned characteristics due to its excellent characteristics compared to a conventional silicon (Si) device, and currently is actively being researched.

In general, a silicon carbide power element includes an ohmic contact layer, which is formed by depositing metal on a silicon carbide power element substrate to provide a low ohmic resistance and forming metal silicide by reacting the metal with a silicon component having high reactivity, and in which current flows smoothly.

A metal pad is formed on the ohmic contact layer. The metal pad is diffused to the ohmic contact layer upon annealing, and hence increases the contact resistivity of the ohmic contact layer. Accordingly, the characteristics of the semiconductor device are deteriorated, and its lifespan is shortened.

The above information disclosed in this Background section is only for enhancement of understanding of the background of the disclosure and therefore it may contain information that does not form the prior art that is already known in this country to a person of ordinary skill in the art.

### SUMMARY

The present disclosure has been made in an effort to provide a semiconductor device structure for an ohmic contact which prevents metal of a pad layer from being diffused to the ohmic contact layer.

An exemplary embodiment of the present disclosure provides a semiconductor device structure for an ohmic contact, including a silicon carbide substrate and an ohmic contact layer disposed on the silicon carbide substrate. A carbon layer is disposed on the ohmic contact layer. An anti-diffusion layer is disposed on the carbon layer, and a pad layer is disposed on the anti-diffusion layer. The anti-diffusion layer is made of any one of tungsten (W), titanium (Ti), titanium nitride (TiN), tantalum (Ta), and tantalum nitride (TaN).

In certain embodiments, the ohmic contact layer may be made of nickel silicide.

In certain embodiments, the carbon layer may comprise carbon migrating from the silicon carbide substrate.

Another embodiment of the present disclosure provides a method for fabricating a semiconductor device structure for an ohmic contact. The method includes forming an ohmic metal layer on a silicon carbide substrate. An ohmic contact layer on the silicon carbide substrate and a carbon layer on the ohmic contact layer are simultaneously formed by annealing the silicon carbide substrate with the ohmic metal layer formed thereon. An anti-diffusion layer is formed on the carbon layer and a pad layer is formed on the anti-diffusion layer.

The anti-diffusion layer comprises any one of tungsten (W), titanium (Ti), titanium nitride (TiN), tantalum (Ta), and tantalum nitride (TaN).

In certain embodiments, the annealing may be carried out in a nitrogen or argon atmosphere of 900° C. or higher.

According to an embodiment of the present disclosure, it is possible to prevent metal of the pad layer from being diffused to the ohmic contact layer by disposing the anti-diffusion layer between the ohmic contact layer and the pad layer.

Accordingly, the semiconductor device can maintain its operating characteristics, and hence the lifespan of the semiconductor device can be improved.

### BRIEF DESCRIPTION OF THE DRAWINGS

FIG. 1 is a cross-sectional view of a semiconductor device structure for an ohmic contact according to an exemplary embodiment of the present disclosure.

FIG. 2 and FIG. 3 are views sequentially showing a method for fabricating a semiconductor device structure for an ohmic structure according to an exemplary embodiment of the present disclosure.

FIG. 4 is a graph comparing the characteristics of a semiconductor device structure for an ohmic contact according to an exemplary embodiment of the present disclosure.

### DETAILED DESCRIPTION

Exemplary embodiments of the present disclosure will be described in detail with reference to the attached drawings. The present disclosure may be modified in many different forms and should not be construed as being limited to the exemplary embodiments set forth herein. Rather, the exemplary embodiments of the present disclosure are provided so that this disclosure will be thorough and complete, and will fully convey the concept of the present disclosure to those skilled in the art.

In the drawings, the thickness of layers and regions may be exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

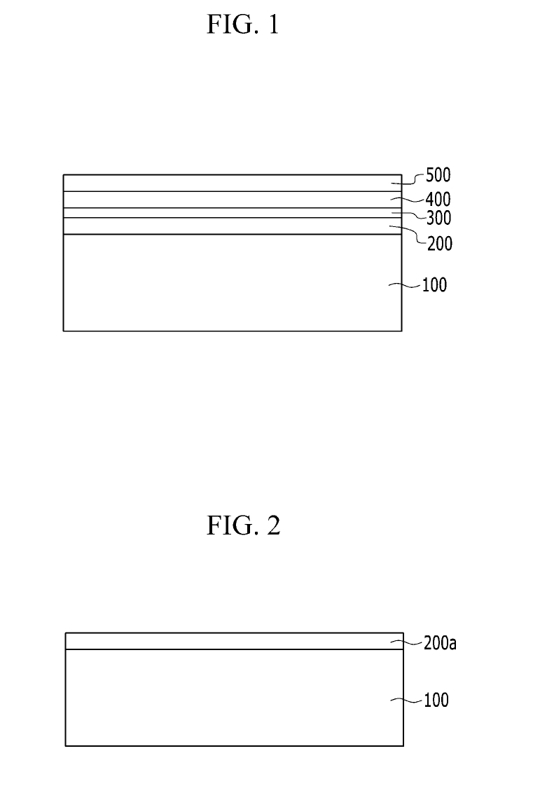

FIG. 1 is a cross-sectional view of a semiconductor device structure for an ohmic contact according to an exemplary embodiment of the present disclosure. Referring to FIG. 1, the semiconductor device structure for the ohmic contact according to the present exemplary embodiment includes a silicon carbide substrate 100, an ohmic contact layer 200, a carbon layer 300, an anti-diffusion layer 400, and a pad layer 500. The ohmic contact layer 200 is disposed on the silicon carbide substrate 100 and is made of nickel silicide (NiSiₓ) in certain embodiments. The carbon layer 300 is disposed on the ohmic contact layer 200 and comprises carbon that migrated from the silicon carbide substrate 100.

An ohmic contact is formed by the ohmic contact layer 200 and a vacancy existing on the silicon carbide substrate 100 from which carbon is removed.

In certain embodiments, the anti-diffusion layer 400 is disposed on the carbon layer 300 and is made of any one of tungsten (W), titanium (Ti), titanium nitride (TiN), tantalum (Ta), and tantalum nitride (TaN). The pad layer 500 is disposed on the anti-diffusion layer 400 and is made of either aluminum (Al) or gold (Au) in certain embodiments. The anti-diffusion layer 400 prevents metal of the pad layer 500 from being diffused to the ohmic contact layer 200 upon high-temperature annealing. Accordingly, the semiconductor device can maintain its operating characteristics even at a high temperature, and hence the lifespan of the semiconductor device can be improved. Moreover, the anti-diffusion layer 400 has excellent adhesion to aluminum or gold, and this helps to improve a contact with the pad layer 500.

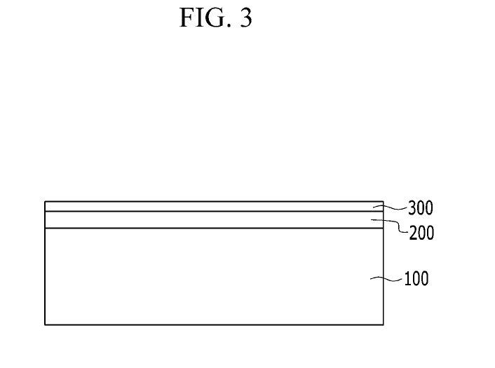

A method for fabricating a semiconductor device structure for an ohmic contact according to an exemplary embodiment of the present disclosure will be described in detail with reference to FIG. 2, FIG. 3, and FIG. 1.

FIG. 2 and FIG. 3 are views sequentially showing a method for fabricating a semiconductor device structure for an ohmic structure according to an exemplary embodiment of the present disclosure. As shown in FIG. 2, a silicon carbide substrate 100 is prepared, and an ohmic metal layer 200a is deposited on the silicon carbide substrate 100. In certain embodiments, the ohmic metal layer 200a is formed of nickel (Ni). As shown in FIG. 3, an ohmic contact layer 200 and a carbon layer 300 are sequentially formed by annealing the silicon carbide substrate 100 having the ohmic metal layer 200a deposited thereon. The annealing is carried out in a nitrogen (N₂) or argon (Ar) atmosphere at a temperature of 900° C. or higher.

When the silicon carbide substrate 100 having the ohmic metal layer 200a deposited thereon is annealed at a temperature of 900° C. or higher, silicon in the silicon carbide substrate 100 reacts with nickel of the ohmic metal layer 200a to form nickel silicide. As a result, an ohmic contact layer 200 is formed. At the same time, some of the carbon in the silicon carbide substrate 100 migrates to the surface of the ohmic metal layer 200a to form a carbon layer 300 on the ohmic contact layer 200. An ohmic contact is formed by the ohmic contact layer 200 and a vacancy existing on the silicon carbide substrate 100 from which carbon is removed.

As shown in FIG. 1, an anti-diffusion layer 400 and a pad layer 500 are sequentially formed on the carbon layer 300. In certain embodiments, the anti-diffusion layer 400 is made of any one of tungsten (W), titanium (Ti), titanium nitride (TiN), tantalum (Ta), and tantalum nitride (TaN). In certain embodiments, the pad layer 500 is made of either aluminum (Al) or gold (Au).

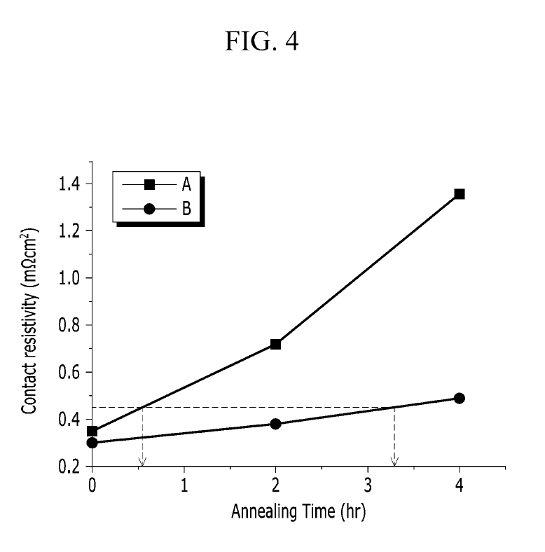

The characteristics of a semiconductor device structure for an ohmic contact according to an exemplary embodiment of the present disclosure will be described with reference to FIG. 4.

FIG. 4 is a graph comparing the characteristics of a semiconductor device structure for an ohmic contact according to an exemplary embodiment of the present disclosure. In FIG. 4, sample A is a structure with no anti-diffusion layer formed between a pad layer and a silicon carbide substrate, and sample B is a structure with an anti-diffusion layer formed between a pad layer and a silicon carbide substrate. Here, the pad layer was formed of aluminum, and the ohmic contact layer is formed of nickel silicide. The anti-diffusion layer was formed of tungsten. Samples A and B were annealed for 2 hours and 4 hours in a nitrogen atmosphere of 600° C.

Referring to FIG. 4, it can be observed that sample B with an anti-diffusion layer showed a significantly lower increase in contact resistivity versus annealing time, compared to sample A with no anti-diffusion layer. That is, it is concluded that sample B with an anti-diffusion layer has a lower increase in contact resistivity because the anti-diffusion layer prevents diffusion of the aluminum of the pad layer to the ohmic contact layer.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device structure for an ohmic contact comprising:
a silicon carbide substrate;
an ohmic contact layer disposed on the silicon carbide substrate;
a carbon layer disposed on the ohmic contact layer;
an anti-diffusion layer disposed on the carbon layer; and
a pad layer disposed on the anti-diffusion layer,
wherein the anti-diffusion layer comprises any one of tungsten (W), titanium (Ti), titanium nitride (TiN), tantalum (Ta), and tantalum nitride (TaN).

2. The semiconductor device structure of claim 1, wherein the ohmic contact layer comprises nickel silicide.

3. The semiconductor device of claim 2, wherein the carbon layer comprises carbon migrating from the silicon carbide substrate.

4. A method for fabricating a semiconductor device structure for an ohmic contact, the method comprising:
forming an ohmic metal layer on a silicon carbide substrate;
simultaneously forming an ohmic contact layer on the silicon carbide substrate and a carbon layer on the ohmic contact layer by annealing the silicon carbide substrate with the ohmic metal layer formed thereon;
forming an anti-diffusion layer on the carbon layer;
forming a pad layer on the anti-diffusion layer,
wherein the anti-diffusion layer comprises any one of tungsten (W), titanium (Ti), titanium nitride (TiN), tantalum (Ta), and tantalum nitride (TaN).

5. The method of claim 4, wherein the ohmic metal layer comprises nickel.

6. The method of claim 5, wherein the annealing is carried out in a nitrogen or argon atmosphere at 900° C. or higher.

7. The method of claim 6, wherein the ohmic contact layer comprises nickel silicide.
